(19) United States
(12) Patent Application Publication
(10) Pub. No.: US 2025/0006881 A1
(43) Pub. Date: Jan. 2, 2025

(54) DISPLAY APPARATUS

(71) Applicant: LG Display Co., Ltd., Seoul (KR)

(72) Inventor: Intae KO, Daegu (KR)

(73) Assignee: LG Display Co., Ltd., Seoul (KR)

(21) Appl. No.: 18/753,448

(22) Filed: Jun. 25, 2024

(30) Foreign Application Priority Data
Jun. 28, 2023 (KR) 10-2023-0083588

(51) Int. Cl. H01L 33/62; G09G 3/32; H01L 25/075; H01L 25/16; H01L 27/12; H01L 27/15; H01L 33/58

(52) U.S. Cl. CPC H01L 33/62; G09G 3/32; H01L 25/0753; H01L 25/167; H01L 27/124; H01L 27/156; H01L 33/58; G09G 2310/0267; G09G 2330/021

(57) ABSTRACT

A display apparatus may include a substrate; a plurality of pixels on the substrate in a row direction and a column direction and including a plurality of sub-pixels; a plurality of sub-pixel circuits in the plurality sub-pixels on the substrate; and a plurality of gate lines on the substrate and connected to the plurality of sub-pixel circuits. Each of the plurality of sub-pixels may include a plurality of sub-light emitting diodes configured to emit light of the same color, at least one sub-light emitting diode of one sub-pixel included in one of the plurality of pixels may be configured to be driven by a gate line, and a sub-light emitting diode of another sub-pixel included in the same one of the plurality of pixels may be configured to be driven by another gate line that is different from the gate line.

### CROSS-REFERENCE TO RELATED APPLICATIONS

This application claims the benefit of and priority to Korean Patent Application No. 10-2023-0083588 filed on Jun. 28, 2023, the entirety of which is incorporated herein by reference for all purposes.

### BACKGROUND

### 1. Technical Field

The present disclosure relates to a display apparatus and more particularly to, for example, without limitation, a display apparatus capable of having improved lifespan.

### 2. Description of the Related Art

As technology in modern society develops, display devices are used in various ways to provide information to users. Display devices are included in electronic signs that simply transmit visual information in one direction, as well as various electronic apparatus that require higher technology to confirm a user input and provide information in response to the confirmed input.

For example, display apparatus may be included in vehicles to provide various information to a driver and passengers of the vehicle. However, the display apparatus of the vehicle needs to display content appropriately so as not to interfere with vehicle operations. For example, the display apparatus needs to limit display of content that may reduce concentration on driving while the vehicle is in operation.

The description of the related art should not be assumed to be prior art merely because it is mentioned in or associated with this section. The description of the related art includes information that describes one or more aspects of the subject technology, and the description in this section does not limit the invention.

### SUMMARY

In one or more aspects, an object to be achieved by the present disclosure is to provide a display apparatus in which anode electrodes of a plurality of sub-pixels extend to different pixels. Thus, the area of anode electrodes disposed in a non-display area can be reduced.

In one or more aspects, another object to be achieved by the present disclosure is to provide a display apparatus with an improved lifespan and reduced power consumption.

Objects of the present disclosure are not limited to the above-mentioned objects, and other objects, which are not mentioned above, can be clearly understood by those skilled in the art from the following descriptions.

According to one or more aspects of the present disclosure, there is provided a display apparatus. The display apparatus comprises: a substrate; a plurality of pixels disposed on the substrate in a row direction and a column direction and including a plurality of sub-pixels; a plurality of sub-pixel circuits disposed in the plurality sub-pixels on the substrate; and a plurality of gate lines disposed on the substrate and connected to the plurality of sub-pixel circuits, wherein each of the plurality of sub-pixels includes a plurality of sub-light emitting diodes configured to emit light of a same color, and at least one sub-light emitting diode of one sub-pixel included in one of the plurality of pixels is configured to be driven by a different gate line than a sub-light emitting diode of another sub-pixel included in the same pixel.

According to one or more aspects of the present disclosure, there is provided a display apparatus. The display apparatus comprises: a substrate; a display area; a non-display area outside the display area; a plurality of pixels including a plurality of sub-pixels disposed in the display area; a plurality of sub-pixel circuits disposed in each of the plurality of pixels; a plurality of sub-light emitting diodes disposed in each of the plurality of sub-pixels; a bank disposed to cover ends of anode electrodes of the plurality of sub-light emitting diodes; and a plurality of lenses disposed on the bank, wherein the plurality of sub-light emitting diodes in each of the plurality of sub-pixels includes a first sub-light emitting diode and a second sub-light emitting diode that are configured to emit light of a same color in a respective one of the plurality of sub-pixels, and at least one of the first sub-light emitting diode and the second sub-light emitting diode of one sub-pixel included in one pixel of the plurality of pixels is connected to a sub-pixel circuit disposed in another pixel of the plurality of pixels.

According to one or more aspects of the present disclosure, there is provided a display apparatus. The display apparatus comprises: a display area; a plurality of pixels in the display area; and a plurality of sub-pixels included in the plurality of pixels, wherein the plurality of pixels comprises a pixel and another pixel that is different from the pixel, the plurality of sub-pixels comprises a sub-pixel and another sub-pixel that is different from the sub-pixel, each of the plurality of sub-pixels comprises a plurality of sub-light emitting diodes, a sub-light emitting diode of the sub-pixel of the pixel is configured to be driven by a transistor included in the pixel, and a sub-light emitting diode of the another sub-pixel of the pixel is configured to be driven by another transistor included in the another pixel.

Other detailed matters of the example embodiments are included in the detailed description and the drawings.

In the display apparatus according to an example embodiment of the present disclosure, a plurality of sub-pixels is driven by using different respective gate lines. Thus, an aperture ratio of the display apparatus can be improved.

In the display apparatus according to an example embodiment of the present disclosure, a lifespan can be improved by improving an aperture ratio.

The effects according to the present disclosure are not limited to the foregoing, and other various effects are included in the present disclosure.

Other apparatuses, devices, methods, features and advantages will be, or will become, apparent to one with skill in the art upon examination of the drawings and detailed description herein. It is intended that all such apparatuses, devices, methods, features and advantages be included within this description, be within the scope of the present disclosure, and be protected by the following claims. Nothing in this section should be taken as a limitation on the claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 illustrates an example of a display apparatus according to an example embodiment of the present disclosure;

FIG. 2 is a functional block view illustrating the display apparatus according to an example embodiment of the present disclosure;

FIG. 3 illustrates an example of a sub-pixel circuit in the display apparatus according to an example embodiment of the present disclosure;

FIG. 4 illustrates an example of a pixel array in the display apparatus according to an example embodiment of the present disclosure;

FIG. 5 and FIG. 6 illustrate examples of sub-pixel circuits applicable to the sub-pixel circuit in the display apparatus according to an example embodiment of the present disclosure;

FIG. 7 is a plan view illustrating a pixel of the display apparatus according to an example embodiment of the present disclosure;

FIG. 8 is an example of a cross-sectional view taken along the line A-A′ of FIG. 7;

FIG. 9 is an example of a cross-sectional view taken along the line B-B′ of FIG. 7;

FIG. 10 is a plan view illustrating a pixel of a display apparatus according to another example embodiment of the present disclosure; and

FIG. 11 is an example of a cross-sectional view taken along the line C-C′ of FIG. 10.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like (or the terms such as a row direction, a column direction, a Y-axis direction, an X-axis direction, a vertical direction, a planar direction, a lengthwise direction, and a widthwise direction) should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “some elements,” “a portion,” “portions,” “at least a portion,” “at least portions,” “a part,” “at least a part,” “parts,” “at least parts,” “one or more,” or the like of the plurality of elements can represent (i) one element of the plurality of elements, (ii) a part of the plurality of elements, (iii) parts of the plurality of elements, (iv) multiple elements of the plurality of elements, or (v) all of the plurality of elements. Moreover, at least a portion (or a part) of an element can represent (i) a portion (or a part) of the element, (ii) one or more portions (or parts) of the element, or (iii) the element, or the entirety of the element. A phrase that a plurality of first elements are connected to a plurality of second elements may describe, for example, that at least a part (or one or more first elements) of a plurality of first elements are connected to at least a part (or one or more second elements) of a plurality of second elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise. In one or more aspects, unless stated otherwise, the term “(N)th” may refer to “Nnd” (e.g., 2nd where n is 2), or “Nrd” (e.g., 3rd where n is 3), and N may be a natural number.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Most of the terms used herein are general terms that have been widely used in the technical art to which the present disclosure pertains. However, some of the terms used herein may have been created reflecting intentions of technicians in this art, precedents, or new technologies. In addition, some of the terms used herein may be arbitrarily chosen by the present applicant. In this case, these terms are defined in detail below. Accordingly, the specific terms used herein should be understood based on the unique meanings thereof and the whole context of the present disclosure.

In addition, the terms described below are terms defined in consideration of functions in the implementation of the present disclosure, and may vary depending on the intention or custom of a user or operator. Therefore, the definition thereof should be made based on the contents throughout this specification.

Transistors constituting a pixel circuit of the present disclosure may include at least one of oxide TFT (Oxide Thin Film Transistor; Oxide TFT), amorphous silicon TFT (a-Si TFT), and low temperature poly silicon (LTPS) TFT.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

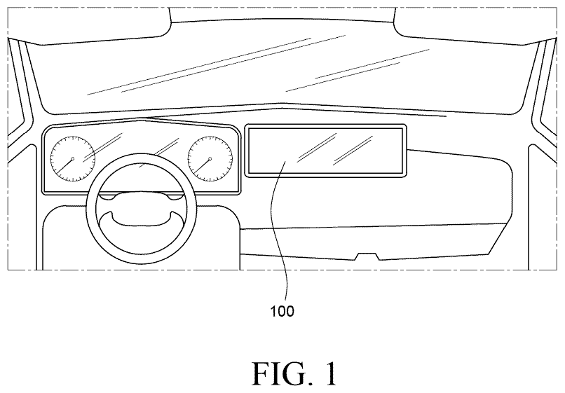

FIG. 1 illustrates an example of a display apparatus according to an example embodiment of the present disclosure.

A display apparatus 100 may be disposed on at least a portion of a dashboard of a vehicle. The dashboard of the vehicle may include components disposed in front of a front seat (e.g., driver seat, passenger seat) in the vehicle. For example, input components for manipulating various functions (e.g., air conditioner, audio system, navigation system) inside the vehicle may be disposed on the dashboard of the vehicle.

The display apparatus 100 according to an example embodiment of the present disclosure may be disposed on the dashboard of the vehicle and may operate as an input unit for manipulating at least some of the various functions of the vehicle. The display apparatus 100 may supply various kinds of information related to the vehicle, for example, driving information of the vehicle (e.g., present speed, residual fuel quantity, mileage), and information related to components of the vehicle (e.g., damage degree of a vehicle tire).

The display apparatus 100 may be disposed to extend across the driver seat and the front passenger seat, which are front seats in the vehicle. A user of the display apparatus 100 may include a driver of the vehicle and a passenger on the front passenger seat in the vehicle. Both of the driver and the passenger may use the display apparatus 100.

FIG. 1 shows only a portion of the display apparatus 100. FIG. 1 shows a display panel among various components of the display apparatus 100. Specifically, for example, the display apparatus 100 shown in FIG. 1 may represent at least a portion of a display area and a non-display area of the display panel. The components other than those shown in FIG. 1 among the components of the display apparatus 100 may be mounted in the interior (or at least a portion) of the vehicle.

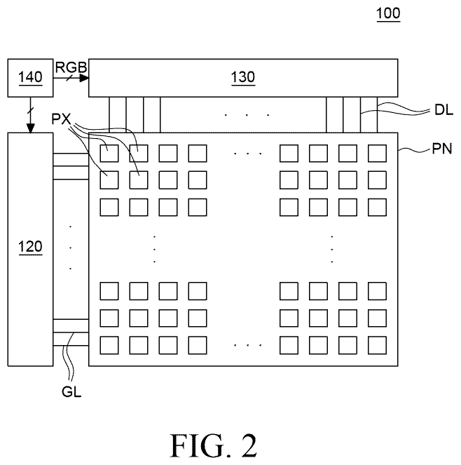

FIG. 2 is a functional block view illustrating the display apparatus according to an example embodiment of the present disclosure.

An electroluminescent display apparatus may be applied to the display apparatus 100 according to an example embodiment of the present disclosure. The electroluminescent display apparatus may be an organic light emitting diode display apparatus, a quantum-dot light emitting diode display apparatus, or an inorganic light emitting diode display apparatus.

Referring to FIG. 2, the display apparatus 100 may include a display panel PN, a data driving circuit 130, a gate driving circuit 120, and a timing controller 140.

The display panel PN may generate an image to be supplied to the user. For example, the display panel PN may generate and display an image to be supplied to the user through a pixel PX including a plurality of sub-pixel circuits.

The data driving circuit 130, the gate driving circuit 120, and the timing controller 140 may supply a signal for operating pixels PX through signal lines, respectively. The signal lines may include data lines DL and gate lines GL.

The data lines DL may be disposed in a column direction, and may include a plurality of lines connected to pixels PX disposed in one column direction. Also, the gate lines GL may be disposed in a row direction, and may include a plurality of lines connected to pixels PX disposed in one row direction.

In some example embodiments, the display apparatus 100 may further include a power unit. In this case, a signal for operating each pixel PX may be supplied through a power line connecting the power unit to the display panel PN. In some example embodiments, the power unit may supply power to the data driving circuit 130 and the gate driving circuit 120. The data driving circuit 130 and the gate driving circuit 120 may be driven based on the power supplied from the power unit.

For example, the data driving circuit 130 may apply a data signal to pixels PX through the data lines DL, respectively, and the gate driving circuit 120 may apply a gate signal to pixels PX through the gate lines GL, respectively. Also, the power unit may supply a power voltage to pixels PX through power voltage supply lines, respectively.

The timing controller 140 may control the data driving circuit 130 and the gate driving circuit 120. For example, the timing controller 140 may realign digital video data input from the outside in accordance with the resolution of the display panel PN and may supply the realigned digital video data to the data driving circuit 130.

The data driving circuit 130 may convert the digital video data input from the timing controller 140 into an analog data voltage based on a data control signal and may supply the analog data voltage to the multiple data lines DL.

The gate driving circuit 120 may generate a scan signal and an emission signal (or emission control signal) based on a gate control signal. For example, the gate driving circuit 120 may include a scan driver and an emission signal driver. The scan driver may generate scan signals in a row sequential manner to drive at least one scan line connected to each pixel row and may supply the scan signals to the scan lines. The emission signal driver may generate emission signals in a row sequential manner to drive at least one emission signal line connected to each pixel row and may supply the emission signals to the emission signal lines.

In some example embodiments, the gate driving circuit 120 may be disposed on the display panel PN in a Gate-driver In Panel (GIP) method. For example, the gate driving circuit 120 may be divided into a plurality of gate driving circuits 120 and then disposed on at least two lateral surfaces of the display panel PN, respectively.

A substrate 10 of the display panel PN may include a display area and a non-display area enclosing the display area.

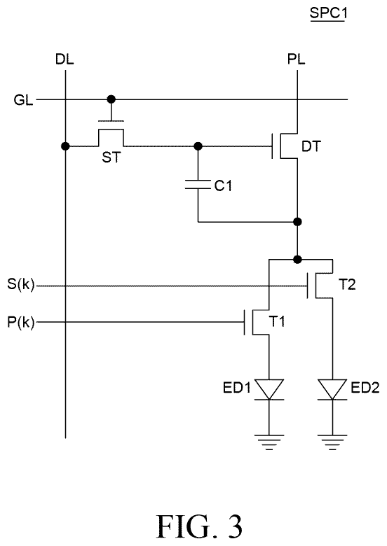

The display area of the display panel PN may include a plurality of pixels PX disposed in the row direction and the column direction. The plurality of pixels PX may be disposed at respective intersections between a plurality of data lines DL (e.g., data line in FIG. 3) and a plurality of gate lines GL (e.g. gate line in FIG. 3).

Each pixel PX may include a plurality of sub-pixels which emits light of different colors. For example, each pixel PX may implement blue, red, and green colors by using three sub-pixels, but is not limited thereto. In some embodiments, the pixel PX may further include a sub-pixel for implementing a specific color (e.g., white).

In the pixel PX, a region implementing blue may be referred to as a blue sub-pixel, a region implementing red may be referred to as a red sub-pixel, and a region implementing green may be referred to as a green sub-pixel.

Each of the plurality of sub-pixels may include a first sub-light emitting diode and a second sub-light emitting diode which emit light of the same color. For example, a first sub-light emitting diode of a sub-pixel may emit light of the same color as a second sub-light emitting diode of the sub-pixel. Each of the plurality of sub-pixels may further include a first lens which refracts light from the first sub-light emitting diode in a specific direction. Each of the plurality of sub-pixels may also include a second lens which refracts light from the second sub-light emitting diode in a specific direction. Thus, a viewing angle of each of the plurality of sub-pixels may be limited by the first lens and the second lens.

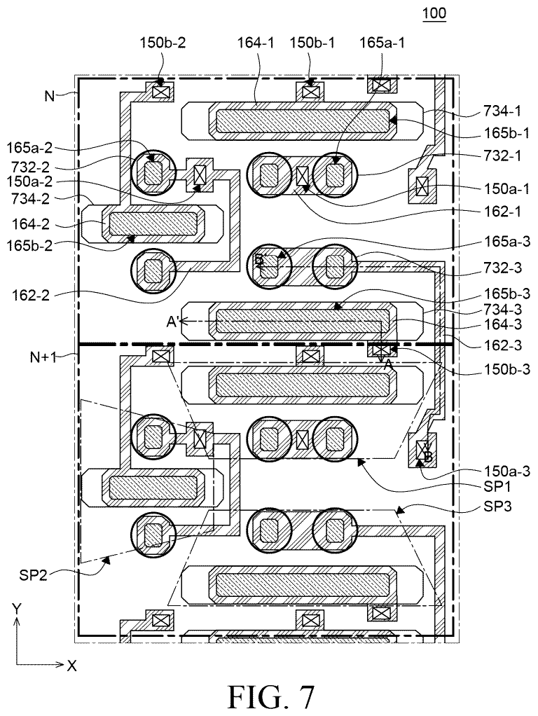

Details of the first lens and the second lens will be described below in more detail with reference to FIG. 7 through FIG. 9.

The non-display area may be disposed along the circumference of (or outside of) the display area. Various components for driving the plurality of sub-pixel circuits disposed in the pixel PX may be disposed in the non-display area. For example, at least a part of the gate driving circuit 120 may be disposed in the non-display area. The non-display area may be referred to as a bezel area.

Meanwhile, one of the plurality of sub-pixels and another one of the plurality of sub-pixels may be driven by different gate lines, respectively. Details of the plurality of sub-pixels will be described below in more detail with reference to FIG. 7 through FIG. 9.

FIG. 3 illustrates an example of a sub-pixel circuit in the display apparatus according to an example embodiment of the present disclosure. Each pixel PX may include a plurality of sub-pixels which emits light of different colors and sub-pixel circuits SPC1 respectively corresponding to the plurality of sub-pixels. FIG. 3 illustrates an example of a sub-pixel circuit SPC1 corresponding to a single sub-pixel disposed in the pixel PX.

Referring to FIG. 3, the sub-pixel circuit SPC1 may include a plurality of transistors DT, ST, T1 and T2, a capacitor C1, and a plurality of sub-light emitting diodes ED1 and ED2.

A driving transistor DT and the capacitor C1 may be connected to a switching transistor ST. A first electrode of the driving transistor DT may be connected to a power voltage supply line PL.

The switching transistor ST may be connected to a gate line GL and supplied with a gate signal. The switching transistor ST may be turned on or turned off by the gate signal. A first electrode of the switching transistor ST may be connected to a data line DL. In this case, the data signal may be supplied to a gate electrode of the driving transistor DT through the switching transistor ST in response to the switching transistor ST being turned-on.

The capacitor C1 may be disposed between the gate electrode and a second electrode of the driving transistor DT. The capacitor C1 can maintain a signal, e.g., a data signal, applied to the gate electrode of the driving transistor DT during one frame.

In some example embodiments, the driving transistor DT, the switching transistor ST, and the capacitor C1 may be elements for driving the light emission of sub-light emitting diodes (e.g., a first sub-light emitting diode ED1 and a second sub-light emitting diode ED2). These elements may be referred to as driving parts, but are not limited to such terms.

The first sub-light emitting diode ED1 may be connected to a first transistor T1 which is turned on or turned off by a first mode signal P(k). The second sub-light emitting diode ED2 may be connected to a second transistor T2 which is turned on or turned off by a second mode signal S(k).

In this case, the first sub-light emitting diode ED1 or the second sub-light emitting diode ED2 may be connected to another component of the sub-pixel circuit SPC1, e.g., the driving transistor DT, depending on a mode. Herein, the mode may be designated by the user's input or may be determined when a predetermined condition is satisfied. For example, when a predesignated first condition is satisfied, the first sub-light emitting diode ED1 may emit light based on the supply of the first mode signal P(k). When a predesignated second condition is satisfied, the second sub-light emitting diode ED2 may emit light based on the supply of the second mode signal S(k). The first condition may include a predesignated condition for driving in a first mode. The second condition may include a predesignated condition for driving in a second mode.

Herein, at least one of the first mode signal P(k) and the second mode signal S(k) may be an emission signal supplied from the gate driving circuit, but is not limited thereto and may be supplied from a separate component.

When the first mode signal P(k) is low, a sub-pixel circuit may operate in the first mode. When the second mode signal S(k) is low, a sub-pixel circuit may operate in the second mode.

The plurality of transistors DT, ST, T1 and T2 of FIG. 3 may include at least one of amorphous silicon, polycrystalline silicon and an oxide semiconductor, such as indium gallium zinc oxide (IGZO). A first electrode or a second electrode of the transistor may be a source electrode or a drain electrode. For example, the first electrode may be a source electrode, and the second electrode may be a drain electrode. As another example, the first electrode may be a drain electrode, and the second electrode may be a source electrode.

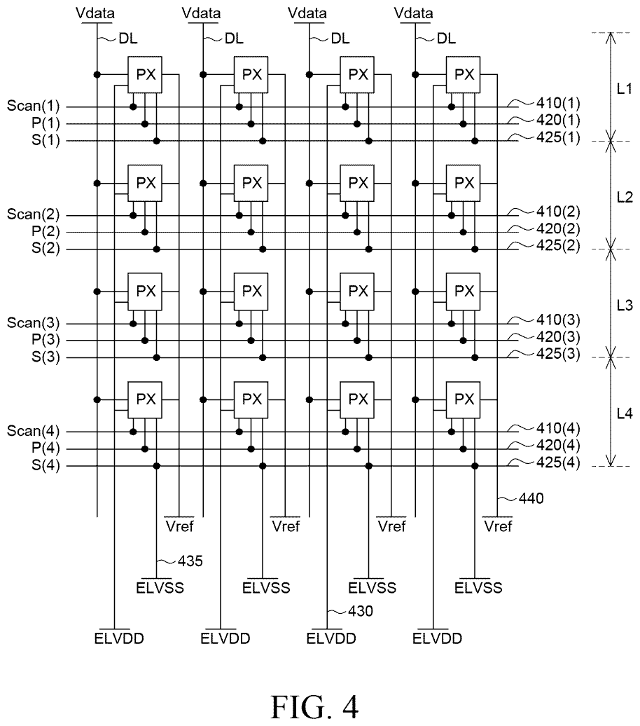

FIG. 4 illustrates an example of a pixel array in the display apparatus according to an example embodiment of the present disclosure.

Referring to FIG. 4, a plurality of horizontal pixel lines L1, L2, L3 and L4 may be provided in a pixel array of a display panel (e.g., the display panel PN in FIG. 2). A plurality of pixels PX horizontally adjacent to each other and commonly connected to the gate lines GL may be disposed in each of the plurality of horizontal pixel lines L1, L2, L3 and LA.

Herein, each of the horizontal pixel lines L1, L2, L3 and LA may refer to a plurality of pixels PX disposed on one line implemented by pixels PX horizontally adjacent to each other. The pixel array may include a data line DL and a first power line 430 for supplying a high-potential power voltage ELVDD to the pixel PX. Also, the pixel array may include a second power line 440 for supplying a reference voltage Vref to the pixel PX and a third power line 435 for supplying a low-potential power voltage ELVSS to the pixel PX.

The pixel array may include a gate line GL.

The gate line GL may include a scan line 410 to which a scan signal SCAN is supplied. In some embodiments, the gate line GL may include a first mode signal line 420 to which a first mode signal P is supplied and a second mode signal line 425 to which a second mode signal S is supplied, but is not limited thereto. The first mode signal line 420 and the second mode signal line 425 may be implemented as separate lines.

The pixel PX may emit light of at least one color. For example, the pixel PX may emit any one of red light, green light, blue light, and white light. The pixel PX may constitute one unit pixel, and the color implemented in the unit pixel may be determined depending on a light emission ratio of red, green, blue, and white. The data line DL, the scan line 410, the first mode signal line 420, and the second mode signal line 425 may be connected to each pixel PX.

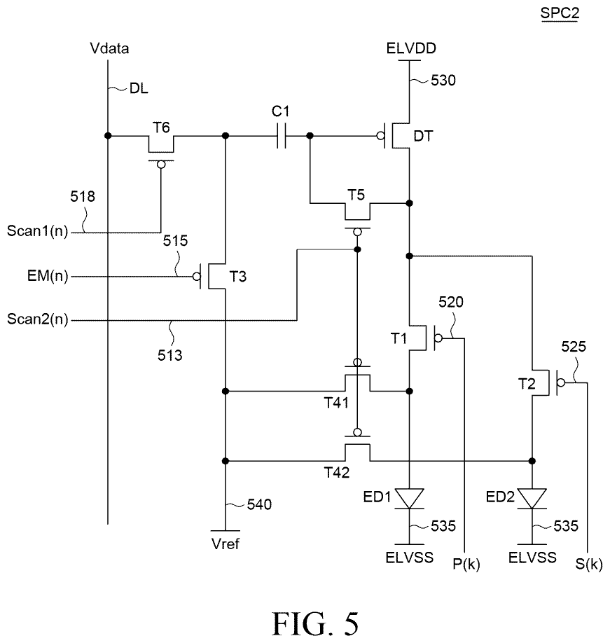

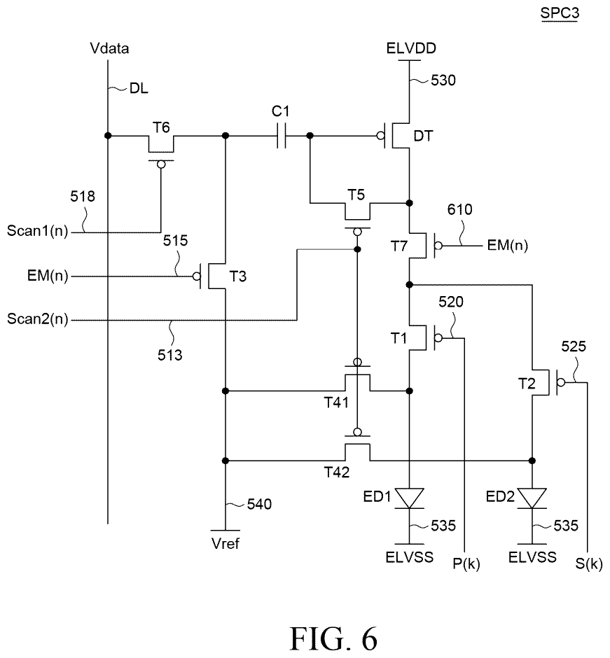

FIG. 5 and FIG. 6 illustrate examples of sub-pixel circuits applicable to the sub-pixel circuit in the display apparatus according to an example embodiment of the present disclosure. Specifically, FIG. 5 and FIG. 6 illustrate examples of sub-pixel circuits different from that illustrated in FIG. 3. FIG. 5 and FIG. 6 are circuit diagrams of a first sub-pixel SP1 and a second sub-pixel SP2 among a plurality of sub-pixels SP.

Referring to FIG. 5, a sub-pixel circuit SPC2 may include eight transistors and one capacitor. At least some of the eight transistors included in the sub-pixel circuit SPC2 may be n-type transistors or p-type transistors. In a p-type transistor, a low level voltage of each driving signal means a voltage for turning on a TFT, and a high level voltage of each driving signal may mean a voltage for turning off the TFT.

Herein, the low level voltage may correspond to a predetermined voltage lower than the high level voltage. For example, the low level voltage may include a voltage in the range of −8 V to −12 V. The high level voltage may correspond to a predetermined voltage higher than the low level voltage. For example, the high level voltage may include a voltage in the range of 12 V to 16 V. In some example embodiments, the low level voltage may be referred to as a first voltage, and the high level voltage may be referred to as a second voltage. In this case, the first voltage may have a value lower than the second voltage.

A first electrode or a second electrode of a transistor to be described below may refer to a source electrode or a drain electrode. However, the terms, such as the first electrode and the second electrode, are used to distinguish each electrode, and do not limit what each electrode corresponds to. Further, the first electrode may not refer to the same electrode for each electrode. For example, a first electrode of the first transistor T1 may refer to a source electrode of the first transistor T1, and a first electrode of a sixth transistor T6 may refer to a drain electrode of the sixth transistor T6.

The driving transistor DT may be connected to the first transistor T1 connected to the first sub-light emitting diode ED1 and the second transistor T2 connected to the second sub-light emitting diode ED2. For example, the second electrode of the driving transistor DT may be connected to the first transistor T1 and the second transistor T2.

The driving transistor DT may be connected to a first power line 530 for supplying the high-potential power voltage ELVDD. For example, the first electrode of the driving transistor DT may be connected to the first power line 530. When the driving transistor DT is turned on, the high-potential power voltage ELVDD supplied through the first power line 530 may be transmitted from the first electrode to the second electrode of the driving transistor DT.

The first transistor T1 may be connected to at least one of the first sub-light emitting diode ED1, the second transistor T2, a (4-1)th transistor T41, a fifth transistor T5, and the driving transistor DT.

The first electrode of the first transistor T1 may be connected to at least one of the driving transistor DT, the second transistor T2, and the fifth transistor T5. A second electrode of the first transistor T1 may be connected to at least one of the (4-1)th transistor T41 and the first sub-light emitting diode ED1. A gate electrode of the first transistor T1 may be connected to a first control line 520. The first transistor T1 may be turned on or turned off by a first control signal P(k) supplied through the first control line 520. When the first transistor T1 is turned on, a voltage supplied through the driving transistor DT may be input into the first sub-light emitting diode ED1 (e.g., an anode electrode of the first sub-light emitting diode ED1).

Herein, the first control signal P(k) may include a (k)th first control signal (k is a positive integer) supplied to a (k)th row in response to a case where the sub-pixel circuit SPC2 is disposed in the (k)th row. The first control signal P(k) is supplied by a mode controller (or mode control circuit), and may control driving (or emission) of the first sub-light emitting diode ED1 on which the first lens is disposed.

The second transistor T2 may be connected to at least one of the second sub-light emitting diode ED2, the first transistor T1, the fifth transistor T5, a (4-2)th transistor T42, and the driving transistor DT.

A first electrode of the second transistor T2 may be connected to at least one of the driving transistor DT, the first transistor T1, and the fifth transistor T5. A second electrode of the second transistor T2 may be connected to at least one of the second sub-light emitting diode ED2 and the (4-2)th transistor T42. A gate electrode of the second transistor T2 may be connected to a second control line 525. The second transistor T2 may be turned on or turned off by a second control signal S(k) supplied through the second control line 525. When the second transistor T2 is turned on, a voltage supplied through the driving transistor DT may be input into the second sub-light emitting diode ED2 (e.g., an anode electrode of the second sub-light emitting diode ED2).

Each of the first sub-light emitting diode ED1 and the second sub-light emitting diode ED2 may include a light emitting diode. For example, each of the first sub-light emitting diode ED1 and the second sub-light emitting diode ED2 may be configured as an organic light emitting diode.

Herein, the second control signal S(k) may include a (k)th second control signal supplied to the (k)th row in response to a case where the sub-pixel circuit SPC2 is disposed in the (k)th row. The second control signal S(k) is supplied by the mode controller, and may control driving (or emission) of the second sub-light emitting diode ED2 on which the second lens is disposed.

The first lens may be disposed on the first sub-light emitting diode ED1. A viewing angle of an area in which the first sub-light emitting diode ED1 is disposed may correspond to a first value due to the first lens. For example, the viewing angle of the area in which the first sub-light emitting diode ED1 is disposed may be equal to or lower than the first value. The second lens may be disposed on the second sub-light emitting diode ED2. A viewing angle of an area in which the second sub-light emitting diode ED2 is disposed may correspond to a second value due to the second lens. The first value may be lower than the second value. For example, the viewing angle of the area in which the second sub-light emitting diode ED2 is disposed may be equal to or higher than the second value.

The sub-pixel circuit SPC2 may be disposed adjacent to the passenger seat. In this case, the area in which the second sub-light emitting diode ED2 of the sub-pixel circuit SPC2 is disposed may have the viewing angle of the second value to provide light to a range corresponding to the driver seat and the passenger seat next to the driver seat. The area in which the first sub-light emitting diode ED1 is disposed may have the viewing angle of the first value to provide light to a range corresponding to the passenger seat.

A third transistor T3 may be connected to at least one of the (4-1)th transistor T41, the (4-2)th transistor T42, a sixth transistor T6, and the capacitor C1. For example, a first electrode of the third transistor T3 may be connected to the sixth transistor T6 and the capacitor C1. A second electrode of the third transistor T3 may be connected to the (4-1)th transistor T41 and the (4-2)th transistor T42. A gate electrode of the third transistor T3 may be connected to an emission signal line 515 for supplying an emission signal EM (n). The emission signal EM (n) may correspond to an (n)th emission signal EM (n) (n is a positive integer) supplied to an (n)th row in response to a case where the sub-pixel circuit SPC2 is disposed in the (n)th pixel row. The third transistor T3 may be turned on or turned off by the emission signal EM (n). The second electrode of the third transistor T3 may be connected to a reference voltage line 540, e.g., the second power line 440 in FIG. 2, for supplying the reference voltage Vref.

The (4-1)th transistor T41 may be connected to at least one of the first transistor T1, the third transistor T3, and the first sub-light emitting diode ED1. For example, a first electrode of the (4-1)th transistor T41 may be connected to the third transistor T3. A second electrode of the (4-1)th transistor T41 may be connected to the first transistor T1 and the first sub-light emitting diode ED1. A gate electrode of the (4-1)th transistor T41 may be connected to an (n)th second scan line 513. Therefore, the (4-1)th transistor T41 may be supplied with an (n)th second scan signal Scan2(n), and may be turned on or turned off by the (n)th second scan signal Scan2(n). The (4-2)th transistor T42 may be connected to at least one of the second transistor T2, the third transistor T3, and the second sub-light emitting diode ED2. For example, a first electrode of the (4-2)th transistor T42 may be connected to the third transistor T3. A second electrode of the (4-2)th transistor T42 may be connected to the second transistor T2 and the second sub-light emitting diode ED2. A gate electrode of the (4-2)th transistor T42 may be connected to the (n)th second scan line 513. Therefore, the (4-2)th transistor T42 may be supplied with the (n)th second scan signal Scan2(n), and may be turned on or turned off by the (n)th second scan signal Scan2(n).

The fifth transistor T5 may be connected to at least one of the driving transistor DT, the (4-1)th transistor T41, the (4-2)th transistor T42, the capacitor C1, the first transistor T1, and the second transistor T2. For example, a first electrode of a fourth transistor T4 may be connected to the driving transistor DT and the capacitor C1. A second electrode of the fifth transistor T5 may be connected to the driving transistor DT, the first transistor T1, and the second transistor T2. A gate electrode of the fifth transistor T5 may be connected to the (n)th second scan line 513 for supplying a second scan signal Scan2(n) in the (n)th row. The fifth transistor T5 may be supplied with the (n)th second scan signal Scan2(n), and may be turned on or turned off by the (n)th second scan signal Scan2(n).

In some example embodiments, an (n)th first scan line 518 may supply an (n)th first scan signal. In this case, a gate electrode of the sixth transistor T6 may be supplied with the (n)th first scan signal. The (n)th second scan line 513 may supply an (n)th second scan signal. In this case, the (n)th second scan signal may be supplied to a gate electrode of each of the (4-1)th transistor T41, the (4-2)th transistor T42, and the fifth transistor T5.

The sixth transistor T6 may be connected to at least one of the third transistor T3 and the capacitor C1. For example, a first electrode of the sixth transistor T6 may be connected to the third transistor T3 and the capacitor C1. A second electrode of the sixth transistor T6 may be connected to the data line DL for supplying a data voltage Vdata. A gate electrode of the sixth transistor T6 may be connected to the (n)th first scan line 518 for supplying the (n)th first scan signal Scan1(n). The sixth transistor T6 may be supplied with the (n)th first scan signal Scan1(n), and may be turned on or turned off by the (n)th first scan signal Scan1(n). When the sixth transistor T6 is turned on, the data voltage Vdata may be transmitted from the second electrode to the first electrode.

The first sub-light emitting diode ED1 and/or the second sub-light emitting diode ED2 may be connected to a third power line 535, e.g., the third power line 435 in FIG. 4, for supplying the low-potential power voltage ELVSS. For example, a cathode electrode of the first sub-light emitting diode ED1 and a cathode electrode of the second sub-light emitting diode ED2 may be connected to the third power line 535, and may be supplied with the low-potential power voltage ELVSS.

In some example embodiments, the low-potential power voltage may include a ground (or ground voltage, 0 V (volt)). For example, the cathode electrode of the first sub-light emitting diode ED1 and the cathode electrode of the second sub-light emitting diode ED2 may be supplied with a voltage corresponding to the ground.

FIG. 6 illustrates a sub-pixel circuit SPC3 according to another example embodiment, which is different from that of FIG. 5. Hereinafter, the same elements and description as in FIG. 5 will be omitted for brevity. The sub-pixel circuit SPC3 of FIG. 6 may include nine transistors and one capacitor. At least some of the nine transistors included in the sub-pixel circuit SPC3 may be an n-type transistor or a p-type transistor.

Referring to FIG. 6, the sub-pixel circuit SPC3 may include a seventh transistor T7. The seventh transistor T7 may be connected to at least one of the first transistor T1, the second transistor T2, the fifth transistor T5, and the driving transistor DT. For example, a first electrode of the seventh transistor T7 may be connected to at least one of the fifth transistor T5 and the driving transistor DT. A second electrode of the seventh transistor T7 may be connected to at least one of the first transistor T1 and the second transistor T2.

A gate electrode of the seventh transistor T7 may be connected to an emission signal line 610 for providing the emission signal EM (n). The seventh transistor T7 may be turned on or turned off by the emission signal EM (n). When the seventh transistor T7 is turned on, a voltage (or current) may be supplied from the first electrode to the second electrode of the seventh transistor T7.

FIG. 7 is a plan view illustrating a pixel of the display apparatus according to an example embodiment of the present disclosure.

FIG. 7 illustrates only first anode electrodes 162-1, 162-2 and 162-3, second anode electrodes 164-1, 164-2 and 164-3, first openings 165a-1, 165a-2 and 165a-3, second openings 165b-1, 165b-2 and 165b-3, first lenses 732-1, 732-2 and 732-3, and second lenses 734-1, 734-2 and 734-3 of first to third sub-pixels SP1, SP2 and SP3 in pixels PX of the display apparatus 100. In an example, each pixel PX may include first to third sub-pixels SP1, SP2 and SP3.

As shown in FIG. 7, the pixel PX of the display apparatus 100 includes the first to third sub-pixels SP1, SP2 and SP3. The first sub-pixel SP1 may be a green sub-pixel, the second sub-pixel SP2 may be a red sub-pixel, and the third sub-pixel SP3 may be a blue sub-pixel.

Herein, the first sub-pixel SP1 and the third sub-pixel SP3 are disposed along a Y-axis direction, and the second sub-pixel SP2 is disposed along an X-axis direction with respect to the first sub-pixel SP1 and the third sub-pixel SP3. For example, the first sub-pixel SP1 may be disposed at (or on) an upper side of one pixel PX, and the third sub-pixel SP3 may be disposed at (or on) a lower side of the one pixel PX. Also, the second sub-pixel SP2 may be disposed between the first sub-pixel SP1 and the third sub-pixel SP3.

Each of the first to third sub-pixels SP1, SP2 and SP3 has a polygonal shape. In this case, the first to third sub-pixels SP1, SP2 and SP3 may have different shapes. However, the present disclosure is not limited thereto. The first to third sub-pixels SP1, SP2 and SP3 may have various shapes.

The first to third sub-pixels SP1, SP2 and SP3 have different areas.

The areas of the first to third sub-pixels SP1, SP2 and SP3 may be determined in consideration of a lifespan and luminous efficiency of the light emitting diode provided in each sub-pixel. For example, if a lifespan of the red light emitting diode is the longest, the second sub-pixel SP2 may have a smaller area than the first sub-pixel SP1 and the third sub-pixel SP3 to make their lifespans uniform. However, the present disclosure is not limited thereto. An area ratio of the first to third sub-pixels SP1, SP2 and SP3 may vary.

Each of the first to third sub-pixels SP1, SP2 and SP3 includes the first sub-light emitting diode ED1 and the second sub-light emitting diode ED2. The first sub-light emitting diode ED1 and the second sub-light emitting diode ED2 within each sub-pixel may have the same structure, and may implement the same color.

The first sub-pixel SP1 includes a first anode electrode 162-1 of the first sub-light emitting diode ED1 and a second anode electrode 164-1 of the second sub-light emitting diode ED2.

The first anode electrode 162-1 and the second anode electrode 164-1 of the first sub-pixel SP1 may be connected to a sub-pixel circuit in a row where the first sub-pixel SP1 is disposed. For example, as for the first sub-pixel SP1 disposed in an (N)th row, the first anode electrode 162-1 provided in the first sub-pixel SP1 is connected to the first transistor T1 disposed in the (N)th row through a first drain contact hole 150a-1. Further, the second anode electrode 164-1 provided in the first sub-pixel SP1 is connected to the second transistor T2 disposed in a second (N)th row through a second drain contact hole 150b-1.

Also, the second sub-pixel SP2 includes a first anode electrode 162-2 of the first sub-light emitting diode ED1 and a second anode electrode 164-2 of the second sub-light emitting diode ED2. The first anode electrode 162-2 and the second anode electrode 164-2 of the second sub-pixel SP2 may be connected to a sub-pixel circuit in a row where the second sub-pixel SP2 is disposed. For example, as for the second sub-pixel SP2 disposed in the (N)th row, the first anode electrode 162-2 provided in the second sub-pixel SP2 is connected to the first transistor T1 disposed in the (N)th row through a first drain contact hole 150a-2. Further, the second anode electrode 164-2 provided in the second sub-pixel SP2 is connected to the second transistor T2 disposed in the (N)th row through a second drain contact hole 150b-2.

Further, the third sub-pixel SP3 includes a first anode electrode 162-3 of the first sub-light emitting diode ED1 and a second anode electrode 164-3 of the second sub-light emitting diode ED2.

At least one of the first sub-light emitting diode ED1 and the second sub-light emitting diode ED2 in the third sub-pixel SP3 of a pixel PX may be connected to a sub-pixel circuit disposed in another pixel PX.

For example, the first anode electrode 162-3 and the second anode electrode 164-3 of the third sub-pixel SP3 may extend to a pixel PX disposed in a row subsequent to a row of the third sub-pixel SP3. The first anode electrode 162-3 and the second anode electrode 164-3 of the third sub-pixel SP3 may be connected to a sub-pixel circuit disposed in the row subsequent to the row of the third sub-pixel SP3. That is, the first sub-light emitting diode ED1 of the third sub-pixel SP3 of a row may be connected to a sub-pixel circuit disposed in a subsequent row (or an adjacent row) and corresponding to the third sub-pixel SP3. Also, the second sub-light emitting diode ED2 of the third sub-pixel SP3 may be connected to the same sub-pixel circuit as the first sub-light emitting diode ED1 of the third sub-pixel SP3. For example, the first and second sub-light emitting diodes ED1 and ED2 of the third sub-pixel SP3 may be connected to the same sub-pixel circuit.

Therefore, as for the third sub-pixel SP3 disposed in the (N)th row, the first anode electrode 162-3 provided in the third sub-pixel SP3 is connected to the first transistor T1 disposed in an (N+1)th row and corresponding to the third sub-pixel SP3 through a first drain contact hole 150a-3. Further, the second anode electrode 164-3 provided in the third sub-pixel SP3 is connected to the second transistor T2 disposed in the (N+1)th row and corresponding to the third sub-pixel SP3 through a second drain contact hole 150b-3.

Thus, the plurality of sub-light emitting diodes ED1 and ED2 of the first sub-pixel SP1 and the second sub-pixel SP2 may be driven by the same gate line GL. The first sub-light emitting diode ED1 and the second sub-light emitting diode ED2 among the plurality of sub-light emitting diodes ED1 and ED2 of the third sub-pixel SP3 may be driven by a different gate line GL than the first sub-pixel SP1 and the second sub-pixel SP2. For example, the first and second sub-light emitting diodes ED1 and ED2 of the third sub-pixel SP3 may be driven by a gate line GL that is different from the gate line GL configured to drive the first and second sub-pixels SP1 and SP2.

For example, the plurality of sub-light emitting diodes ED1 and ED2 of the first sub-pixel SP1 and the second sub-pixel SP2 may be driven by an (N)th gate line. Further, the first sub-light emitting diode ED1 of the third sub-pixel SP3 may be driven by an (N+1)th gate line. The second sub-light emitting diode ED2 of the third sub-pixel SP3 may also be driven by the same (N+1)th gate line that is configured to drive the first sub-light emitting diode ED1 of the third sub-pixel SP3.

In the first to third sub-pixels SP1, SP2 and SP3, at least one or each of the first openings 165a-1, 165a-2 and 165a-3 exposing the respective first anode electrode is formed on the respective one of the first anode electrodes 162-1, 162-2 and 162-3. Also, in the first to third sub-pixels SP1, SP2 and SP3, at least one or each of the second openings 165b-1, 165b-2 and 165b-3 exposing the respective second anode electrode is formed on the respective one of the second anode electrodes 164-1, 164-2 and 164-3.

With respect to the X-Y plan view, each of the first openings 165a-1, 165a-2, and 165a-3 may have a shape in which a length in the X-axis direction is substantially the same as a length in the Y-axis direction. Each of the second openings 165b-1, 165b-2 and 165b-3 may have a polygonal shape in which a length in the X-axis direction is greater than a length in the Y-axis direction. Each of the second openings 165b-1, 165b-2 and 165b-3 may have a greater area than the respective at least one first opening 165a-1, 165a-2 or 165a-3.

Specifically, in the first sub-pixel SP1, two first openings 165a-1 may be disposed on the first anode electrode 162-1 and one second opening 165b-1 may be disposed on the second anode electrode 164-1. The above-described two first openings 165a-1 and one second opening 165b-1 may be disposed in the Y-axis direction to be spaced apart from each other.

In the second sub-pixel SP2, two first openings 165a-2 disposed in the Y-axis direction may be disposed on the first anode electrode 162-2, and one second opening 165b-2 may be disposed on the second anode electrode 164-2. The above-described two first openings 165a-2 and one second opening 165b-2 may be disposed in the Y-axis direction to be spaced apart from each other.

In the third sub-pixel SP3, two first openings 165a-3 disposed in the X-axis direction may be disposed on the first anode electrode 162-3 and one second opening 165b-3 may be disposed on the second anode electrode 164-3. The above-described two first openings 165a-3 and one second opening 165b-3 may be disposed in the Y-axis direction to be spaced apart from each other.

Hemispherical first lenses 732-1, 732-2 and 732-3 are disposed so as to correspond to the first openings 165a-1, 165a-2 and 165a-3, respectively. Also, semicylindrical second lenses 734-1, 734-2 and 734-3 are disposed so as to correspond to the second openings 165b-1, 165b-2 and 165b-3, respectively.

The first lenses 732-1, 732-2 and 732-3 are disposed so as to cover the first openings 165a-1, 165a-2 and 165a-3, respectively. With respect to the X-Y plan view, each of the first lenses 732-1, 732-2 and 732-3 may have a greater area than the respective one of the first openings 165a-1, 165a-2 and 165a-3. The second lenses 734-1, 734-2 and 734-3 are disposed so as to cover the second openings 165b-1, 165b-2 and 165b-3, respectively. With respect to the X-Y plan view, each of the second lenses 734-1, 734-2 and 734-3 may have a greater area than the respective one of the second openings 165b-1, 165b-2 and 165b-3.

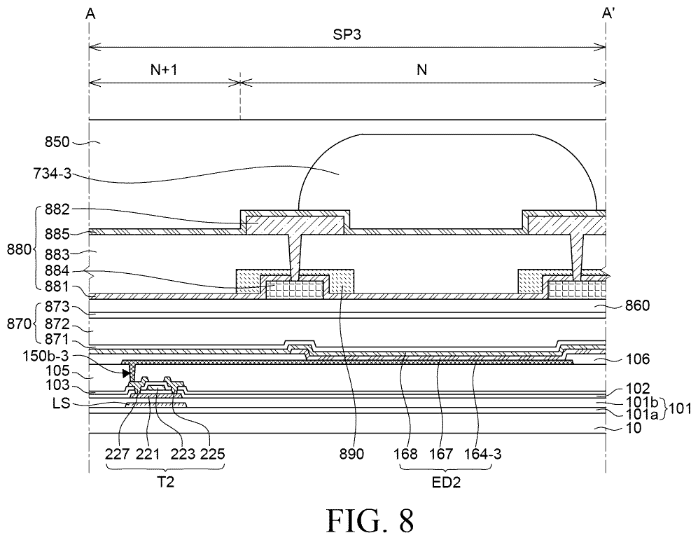

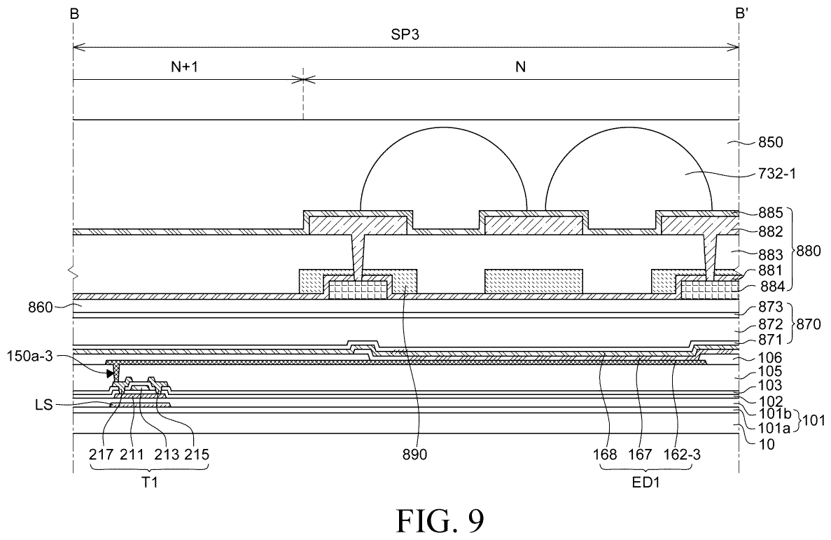

Hereinafter, the first sub-light emitting diode ED1 and the second sub-light emitting diode ED2 will be described in more detail with respect to FIG. 8 and FIG. 9.

FIG. 8 is an example of a cross-sectional view taken along the line A-A′ of FIG. 7. FIG. 9 is an example of a cross-sectional view taken along the line B-B′ of FIG. 7. FIG. 8 is an example of a cross-sectional view of the second sub-light emitting diode ED2 of the third sub-pixel SP3. FIG. 9 is an example of a cross-sectional view of the first sub-light emitting diode ED1 of the third sub-pixel SP3.

Referring to FIG. 8 and FIG. 9, in the display apparatus 100 according to an example embodiment of the present disclosure, a buffer film 101, a gate insulating film 102, and an interlayer insulating film 103 may be disposed on the substrate 10. Also, an overcoating layer 105, a bank 106, a light shielding layer LS, the first transistor T1, the second transistor T2, the first sub-light emitting diode ED1, and the second sub-light emitting diode ED2 may be disposed on the substrate 10. Further, an encapsulation member 870, a buffer layer 860, a touch sensing unit 880, a light shielding pattern 890, a lens protection film 850, the first lens 732-3, and the second lens 734-3 may be disposed on the substrate 10.

The buffer film 101 may be disposed on the substrate 10. The buffer film 101 may include a first buffer film 101a and a second buffer film 101b.

The first buffer film 101a may be disposed on the substrate 10. The first buffer film 101a may suppress permeation of moisture or impurities through the substrate 10. The first buffer film 101a may contain an inorganic insulating material, such as silicon oxide (SiOx) or silicon nitride (SiNx). The first buffer film 101a may have a multilayer structure. For example, the first buffer film 101a may have a structure in which a film of silicon nitride (SiNx) and a film of silicon oxide (SiOx) are laminated.

The light shielding layer LS may be disposed on the first buffer film 101a. The light shielding layer LS may be disposed to overlap at least a first semiconductor layer 211 of the first transistor T1 and at least a second semiconductor layer 221 of the second transistor T2. Thus, the light shielding layer LS may shield light incident to the first semiconductor layer 211 and the second semiconductor layer 221. Meanwhile, the light shielding layer LS is illustrated as a single layer in the drawings, but the light shielding layer LS may be composed of a plurality of layers. The light shielding layer LS may be made of various conductive materials, such as magnesium (Mg), aluminum (Al), nickel (Ni), chromium (Cr), molybdenum (Mo), tungsten (W), gold (Au), or an alloy thereof.

The second buffer film 101b may be disposed on the light shielding layer LS. The second buffer film 101b may protect the first transistor T1 and the second transistor T2 from impurities, such as alkali ions leaking from the substrate 10. Also, the second buffer film 101b may increase adhesion between the substrate 10 and the layers formed on the second buffer film 101b. Further, the second buffer film 101b may contain an inorganic insulating material, such as silicon oxide (SiOx) or silicon nitride (SiNx). The second buffer film 101b may have a multilayer structure. For example, the second buffer film 101b may have a structure in which a film of silicon nitride (SiNx) and a film of silicon oxide (SiOx) are laminated.

The first transistor T1 and the second transistor T2 may be disposed on the buffer film 101.

Referring to FIG. 9, the first transistor T1 may include the first semiconductor layer 211, a first gate electrode 213, a first source electrode 215, and a first drain electrode 217. Referring to FIG. 8, the second transistor T2 may include the second semiconductor layer 221, a second gate electrode 223, a second source electrode 225, and a second drain electrode 227. The second semiconductor layer 221 may be located on the same layer as the first semiconductor layer 211. Also, the second gate electrode 223 may be located on the same layer as the first gate electrode 213. Further, the second source electrode 225 and the second drain electrode 227 may be located on the same layer as the first source electrode 215 and the first drain electrode 217.

The patterned first semiconductor layer 211 and second semiconductor layer 221 are disposed in the first sub-light emitting diode ED1 and the second sub-light emitting diode ED2, respectively, on the buffer film 101.

Each of the first semiconductor layer 211 and the second semiconductor layer 221 may be made of an oxide semiconductor material. Alternatively, each of the first semiconductor layer 211 and the second semiconductor layer 221 may be made of polycrystalline silicon. In this case, impurities may be doped into both edges of each of the first semiconductor layer 211 and the second semiconductor layer 221.

The gate insulating film 102 made of an insulating material may be disposed on the first semiconductor layer 211 and the second semiconductor layer 221. The gate insulating film 102 may contain an insulating material. For example, the gate insulating film 102 may contain an inorganic insulating material, such as silicon oxide (SiO) and silicon nitride (SiN). The gate insulating film 102 may contain a material having a high dielectric constant. For example, the gate insulating film 102 may contain a high-K material, such as hafnium oxide (HfO). The gate insulating film 102 may have a multilayer structure.

The gate insulating film 102 may extend between a semiconductor layer and a gate electrode of a transistor. For example, the gate electrodes of the driving transistor DT and the switching transistor ST may be insulated from the semiconductor layers of the driving transistor DT and the switching transistor ST by the gate insulating film 102. The gate insulating film 102 may cover a first semiconductor layer and a second semiconductor layer of each pixel PX. The gate electrodes of the driving transistor DT and the switching transistor ST may be located on the gate insulating film 102.

Meanwhile, in FIG. 8 and FIG. 9, the gate insulating film 102 is illustrated as being formed on the entire surface of the substrate 10. However, the gate insulating film 102 may also be patterned in the same shape as the first gate electrode 213 and the second gate electrode 223.

The first gate electrode 213 and the second gate electrode 223 made of a conductive material, such as a metal, may be disposed on the gate insulating film 102 so as to correspond to the first semiconductor layer 211 and the second semiconductor layer 221, respectively. Also, a gate line (not shown) may be disposed on the gate insulating film 102. The gate line GL may extend along the row direction.

The interlayer insulating film 103 may be disposed on the first gate electrode 213 and the second gate electrode 223. The interlayer insulating film 103 may contain an insulating material. For example, the interlayer insulating film 103 may contain an inorganic insulating material, such as silicon oxide (SiO) and silicon nitride (SiN). The interlayer insulating film 103 may be located on the gate insulating film 102. The interlayer insulating film 103 may extend between the gate electrode and the source electrode and between the gate electrode and the drain electrode of each of the driving transistor DT and the switching transistor ST. For example, the source electrode and the drain electrode of each of the driving transistor DT and the switching transistor ST may be insulated from the gate electrode by the interlayer insulating film 103. The interlayer insulating film 103 may cover the gate electrode of each of the driving transistor DT and the switching transistor ST. A source electrode and a drain electrode of each pixel PX may be located on the interlayer insulating film 103. The gate insulating film 102 and the interlayer insulating film 103 may expose a source region and a drain region of each semiconductor pattern located in each pixel PX.

The first source electrode 215 and the first drain electrode 217 are in contact with the first semiconductor layer 211 through a contact hole of the interlayer insulating film 103. Also, the second source electrode 225 and the second drain electrode 227 are in contact with the second semiconductor layer 221 through a contact hole of the interlayer insulating film 103. Although not illustrated in the drawings, the data line DL may extend along a direction perpendicular to the row direction and intersect the gate line GL to define each pixel PX.

Meanwhile, the first transistor T1 may have the same structure as the switching transistor ST and the driving transistor DT. For example, the first semiconductor layer 211 may be located between the buffer film 101 and the gate insulating film 102. Also, the first gate electrode 213 may be located between the gate insulating film 102 and the interlayer insulating film 103. The first source electrode 215 and the first drain electrode 217 may be located between the interlayer insulating film 103 and the overcoating layer 105. The first gate electrode 213 may overlap a channel region of the first semiconductor layer 211. The first source electrode 215 may be electrically connected to a source region of the first semiconductor layer 211. The first drain electrode 217 may be electrically connected to a drain region of the first semiconductor layer 211.

In the display apparatus 100, the first transistor T1 may be formed at the same time as the switching transistor ST and the driving transistor DT. The first transistor T1 may be formed at the same time as the second transistor T2.

Although not illustrated in FIG. 8 and FIG. 9, the first transistor T1 may be electrically connected between a drain electrode of the driving transistor DT and the first anode electrode 162-3 of the first sub-light emitting diode ED1. The second transistor T2 may be electrically connected between the drain electrode of the driving transistor DT and the second anode electrode 164-3 of the second sub-light emitting diode ED2.

The overcoating layer 105 may be disposed on the first transistor T1 and the second transistor T2. The overcoating layer 105 may contain an insulating material. The overcoating layer 105 may contain an organic insulating material. A top surface of the overcoating layer 105 facing the substrate 10 may be a flat surface.

The first sub-light emitting diode ED1 and the second sub-light emitting diode ED2 of each pixel PX may be disposed on the overcoating layer 105 of the pixel PX.

Referring to FIG. 9, the first sub-light emitting diode ED1 may include the first anode electrode 162-3, an emission layer 167, and a cathode electrode 168 which are sequentially laminated on the substrate 10.

The first anode electrode 162-3 may contain a conductive material. The first anode electrode 162-3 may contain a material having a high reflectivity. For example, the first anode electrode 162-3 may contain a metal, such as aluminum (Al) and silver (Ag). The first anode electrode 162-3 may have a multilayer structure. For example, the first anode electrode 162-3 may have a structure in which a reflective electrode made of a metal is located between transparent electrodes made of a transparent conductive material, such as indium tin oxide (ITO) and indium zinc oxide (IZO).

The first anode electrode 162-3 of the first sub-light emitting diode ED1 may be connected to the first transistor T1 of a pixel circuit disposed in an adjacent row through a contact hole penetrating the overcoating layer 105. For example, the first anode electrode 162-3 of the first sub-light emitting diode ED1 disposed in the (N)th row may be electrically connected to the first drain electrode 217 (or the first source electrode 215) of the first transistor T1 disposed in the (N+1)th row through the first drain contact hole 150a-3.

The second sub-light emitting diode ED2 may implement the same color as the first sub-light emitting diode ED1. The second sub-light emitting diode ED2 may have the same structure as the first sub-light emitting diode ED1. For example, the second sub-light emitting diode ED2 may include the second anode electrode 164-3, the emission layer 167, and the cathode electrode 168 which are sequentially stacked (or laminated) on the substrate 10 as shown in FIG. 8.

The second anode electrode 164-3 of the second sub-light emitting diode ED2 may be connected to the second transistor T2 of a pixel circuit disposed in an adjacent row (or a subsequent row) through a contact hole penetrating the overcoating layer 105. For example, the second anode electrode 164-3 of the second sub-light emitting diode ED2 disposed in the (N)th row may be electrically connected to the second drain electrode 227 (or the second source electrode 225) of the second transistor T2 disposed in the (N+1)th row through the second drain contact hole 150b-3.

The second anode electrode 164-3 of each pixel PX may be spaced apart from the first anode electrode 162-3 of the pixel PX. For example, the bank 106 may be located between the first anode electrode 162-3 and the second anode electrode 164-3 of each pixel PX. The bank 106 may contain an insulating material. For example, the bank 106 may contain an organic insulating material. The bank 106 may contain a different material from the overcoating layer 105.

The second anode electrode 164-3 of each pixel PX may be insulated from the first anode electrode 162-3 of the pixel PX by the bank 106. For example, the bank 106 may cover an edge of the first anode electrode 162-3 and an edge of the second anode electrode 164-3 in each pixel PX. Herein, the bank 106 may include the first opening 165a-3 and the second opening 165b-3 which expose the first anode electrode 162-3 of the first sub-light emitting diode ED1 and the second anode electrode 164-3 of the second sub-light emitting diode ED2.

The emission layer 167 may generate light with a luminance corresponding to a voltage difference between the first anode electrode 162-3 and the cathode electrode 168. For example, the emission layer 167 may include an emission material layer EML containing a light emitting material. The light emitting material may include an organic material, an inorganic material, or a hybrid material.

The emission layer 167 may have a multilayer structure. For example, the emission layer 167 may further include at least one of a hole injection layer HIL, a hole transport layer HTL, an electron transport layer ETL, and an electron injection layer EIL.

The cathode electrode 168 may contain a conductive material. The cathode electrode 168 may contain a different material from the first anode electrode 162-3. The cathode electrode 168 may have a higher transmittance than the first anode electrode 162-3. For example, the cathode electrode 168 may be a transparent electrode made of a transparent conductive material, such as ITO and IZO. Therefore, in the display apparatus 100 according to an example embodiment of the present disclosure, light generated by the emission layer 167 may be emitted through the cathode electrode 168.

Meanwhile, the emission layer 167 may be spaced apart from each other between the first sub-light emitting diode ED1 and the second sub-light emitting diode ED2.

The emission layer 167 and the cathode electrode 168 of the first sub-light emitting diode ED1 located in each pixel PX may be stacked (or laminated) on a portion of the first anode electrode 162-3 exposed through the first opening 165a-3 of the bank 106. The emission layer 167 and the cathode electrode 168 of the second sub-light emitting diode ED2 located in each pixel PX may be laminated on a portion of the second anode electrodes 164-1, 164-2 and 164-3 exposed through the second opening 165b-3 of the bank 106. Meanwhile, the first opening 165a-3 may have a smaller size than the second opening 165b-3 in each pixel PX.

The cathode electrode 168 of the first sub-light emitting diode ED1 may be electrically connected to the cathode electrode 168 of the second sub-light emitting diode ED2 in each pixel PX. For example, a voltage to be applied to the cathode electrode 168 of the second sub-light emitting diode ED2 located in each pixel PX may be equal to a voltage to be applied to the cathode electrode 168 of the first sub-light emitting diode ED1 located in the pixel PX. The cathode electrode 168 of the second sub-light emitting diode ED2 in each pixel PX may be formed at the same time as the cathode electrode 168 of the first sub-light emitting diode ED1 in the pixel PX. Thus, the cathode electrode 168 of the first sub-light emitting diode ED1 may contain the same material as the cathode electrode 168 of the second sub-light emitting diode ED2. Also, the cathode electrode 168 of the first sub-light emitting diode ED1 and the cathode electrode 168 of the second sub-light emitting diode ED2 of each pixel PX may extend onto the bank 106 so as to be connected to each other.

The encapsulation member 870 may be located on the first sub-light emitting diode ED1 and the second sub-light emitting diode ED2 of each pixel PX. The encapsulation member 870 may suppress damage to the light emitting diodes ED1 and ED2 caused by external moisture and impacts. The encapsulation member 870 may have a multilayer structure. For example, the encapsulation member 870 may include a first encapsulation layer 871, a second encapsulation layer 872, and a third encapsulation layer 873 which are sequentially laminated, but is not limited thereto.

The encapsulation member 870 includes the first encapsulation layer 871, the second encapsulation layer 872, and a third encapsulation layer 873.

The first encapsulation layer 871 may be disposed on the first sub-light emitting diode ED1 and the second sub-light emitting diode ED2 to suppress permeation of moisture or oxygen. The first encapsulation layer 871 may be made of an inorganic material, such as silicon oxide (SiOx), silicon nitride (SiNx), silicon oxynitride (SiNxOy), or aluminum oxide (AlyOz), but is not limited thereto.

The second encapsulation layer 872 may be disposed on the first encapsulation layer 871 to planarize its surface. Also, the second encapsulation layer 872 may cover foreign materials or particles which may be generated during a manufacturing process. The second encapsulation layer 872 may be made of an organic material, such as silicon oxycarbon (SiOxCz), or acryl- or epoxy-based resin, but is not limited thereto.

The third encapsulation layer 873 may be disposed on the second encapsulation layer 872 to suppress permeation of moisture or oxygen, similarly to the first encapsulation layer 871. In this case, the third encapsulation layer 873 and the first encapsulation layer 871 may be formed to seal the second encapsulation layer 872. Therefore, moisture or oxygen permeating into the first sub-light emitting diode ED1 and the second sub-light emitting diode ED2 can be reduced more effectively by the third encapsulation layer 873. The third encapsulation layer 873 may be made of an inorganic material, such as silicon oxide (SiOx), silicon nitride (SiNx), silicon oxynitride (SiNxOy), or aluminum oxide (AlyOz), but is not limited thereto.

The buffer layer 860 may be disposed on the encapsulation member 870. The buffer layer 860 may contain an inorganic insulating material, such as silicon oxide (SiOx) and silicon nitride (SiNx), and have a multilayer structure.

The touch sensing unit 880 may be disposed on the buffer layer 860. The touch sensing unit 880 may be disposed in the display area including the first sub-light emitting diode ED1 and the second sub-light emitting diode ED2 and configured to sense a touch input. The touch sensing unit 880 may sense external touch information provided by a finger of the user or a touch pen. The touch sensing unit 880 includes a first inorganic insulating layer 881, a second inorganic insulating layer 885, an organic layer 883, a bridge electrode 884, and a touch electrode 882.

The bridge electrode 884 may be disposed on the buffer layer 860. The bridge electrode 884 may serve to connect the touch electrode 882 extending in the row direction and the touch electrode 882 extending in the column direction at their intersection where they are disconnected from each other.

The first inorganic insulating layer 881 may be disposed on the bridge electrode 884. The first inorganic insulating layer 881 may cover a top surface and a lateral surface of the bridge electrode 884. The first inorganic insulating layer 881 may be made of an inorganic material. For example, the first inorganic insulating layer 881 may be made of an inorganic material, such as silicon nitride (SiNx) and silicon oxynitride (SiON), but is not limited thereto.

The light shielding pattern 890 is provided on the first inorganic insulating layer 881. The light shielding pattern 890 may be formed among the first to third sub-pixels SP1, SP2 and SP3 adjacent to each other or formed between the first sub-light emitting diode ED1 and the second sub-light emitting diode ED2. Also, the light shielding pattern 890 may be disposed to overlap the bridge electrode 884.

The light shielding pattern 890 may be a black matrix, and may be made of black resin, chrome oxide, or the like.

The organic layer 883 may be disposed on the first inorganic insulating layer 881 and the light shielding pattern 890. The organic layer 883 may secure a gap between the light shielding pattern 890 and the components disposed thereon. For example, the organic layer 883 may secure a gap between the light shielding pattern 890 and the bridge electrode 884, the first lenses 732-1 732-2 and 732-3, and the second lenses 734-1, 734-2 and 734-3. The organic layer 883 may be made of an organic insulating material. For example, the organic layer 883 may be made of photo acryl, benzocyclobutene (BCB), polyimide (PI), or polyamide (PA), but is not limited thereto.

The touch electrode 882 may be disposed on the organic layer 883. The touch electrode 882 may be disposed flat along a top surface of the organic layer 883. The touch electrode 882 may be disposed in the row direction and the column direction.

The second inorganic insulating layer 885 may be disposed on the touch electrode 882. The second inorganic insulating layer 885 may cover a top surface and a lateral surface of the touch electrode 882. The second inorganic insulating layer 885 may be made of an inorganic material. For example, the second inorganic insulating layer 885 may be made of an inorganic material, such as silicon nitride (SiNx) and silicon oxynitride (SiON), but is not limited thereto.

Although not illustrated in FIG. 8 and FIG. 9, a routing line may be disposed in the non-display area in order to extend the touch electrode 882 disposed in an outermost region of the display area to a touch pad disposed in the non-display area.

FIG. 8 and FIG. 9 illustrate a touch on encapsulation (TOE) structure in which the touch sensing unit 880 is located on the display panel PN. However, a structure of the touch sensing unit 880 according to example embodiments of the present disclosure is not limited thereto.

The first lens 732-3 and the second lens 734-3 may be located on the touch sensing unit 880 so as to correspond to each pixel PX.

Specifically, in the third sub-pixel SP3, two first lenses 732-3 may be disposed to cover two first openings 165a-3, respectively. Also, one second lens 734-3 may be disposed to cover one second opening 165b-3.

Therefore, a plurality of first lenses 732-3 corresponds to the first light emitting diode ED1. Also, a plurality of second lenses 734-3 corresponds to the second light emitting diode ED2.

Light generated by the first sub-light emitting diode ED1 of each pixel PX may be emitted through the first lens 732-3 of the pixel PX. Also, light generated by the second sub-light emitting diode ED2 of each pixel PX may be emitted through the second lens 734-3 of the pixel PX.

For example, a traveling direction of light passing through the first lens 732-3 may be limited to a first direction and/or a second direction. For example, the first lens 732-3 located in each pixel PX may have a circular shape when viewed from the top. In this case, the traveling direction of light emitted from the first lens 732-3 of the pixel PX may be limited to the first direction and the second direction. For example, content supplied through the first lens 732-3 of the pixel PX may not be shared by people around the user. When the content is supplied through the first lens 732-3, it may be referred to as the first mode in which the content is supplied in a first viewing angle range narrower than a second viewing angle range supplied by the second lens 734-3.

A traveling direction of light passing through the second lens 734-3 may not be limited to the first direction or the second direction. For example, the second lens 734-3 may have a shape in which light in at least one direction may not be limited. For example, the second lens 734-3 located in each pixel PX may have a bar shape extending in one direction when viewed from the top.

In this case, a traveling direction of light emitted from the second sub-light emitting diode ED2 of the pixel PX may not be limited to the first direction or the second direction. For example, content (e.g., images) supplied through the second lens 734-3 of the pixel PX may be shared by people adjacent to the user in the first direction and/or the second direction. When the content is supplied through the second lens 734-3, it may be referred to as the second mode in which the content is supplied in the second viewing angle range wider than the first viewing angle range supplied by the first lens 732-3.

FIG. 8 and FIG. 9 illustrate only cross-sectional views of the third sub-pixel SP3. However, the first sub-pixel SP1 and the second sub-pixel SP2 may have the same structure as the third sub-pixel SP3 only except that the first anode electrode 162-1 and the second anode electrode 164-1 of the first sub-pixel SP1 and the first anode electrode 162-2 and the second anode electrode 164-2 of the second sub-pixel SP2 are connected to a pixel circuit disposed in the same row as the corresponding pixel. For example, the first and second anode electrodes 162-1, 164-1, 162-2 and 164-2 of the first and second subpixels SP1 and SP2 of a pixel in a row may be connected to a pixel circuit disposed in the same row.

In a typical display apparatus, pixels disposed in the same row are driven by the same gate line. For example, if a pixel includes a first sub-pixel, a second sub-pixel, and a third sub-pixel, anode electrodes of the first sub-pixel, the second sub-pixel, and the third sub-pixel, respectively, extend toward a sub-pixel circuit of the pixel in which the first sub-pixel, the second sub-pixel, and the third sub-pixel are disposed. Thus, the first sub-pixel, the second sub-pixel, and the third sub-pixel are driven by the same gate line.

However, if a plurality of sub-pixels is spaced apart from each other by different intervals in one pixel, distances between the respective sub-pixels and a sub-pixel circuit may be different from each other. For example, in one pixel, a distance between a third sub-pixel and its sub-pixel circuit may be greater than a distance between a second sub-pixel and its sub-pixel circuit and may be greater than a distance between a first sub-pixel and its sub-pixel circuit. Herein, a first anode electrode and a second anode electrode of each of the first to third sub-pixels may extend toward the respective sub-pixel circuit. This is to connect each of the first to third sub-pixels to the respective sub-pixel circuit disposed in the same row. In this case, an area where the extended first and second anode electrodes are disposed needs to be secured. Therefore, an emission area may be decreased relatively. Thus, an aperture ratio may decrease as much as a decrease in the emission area. Accordingly, as the aperture ratio decreases, the amount of current required for driving the display apparatus increases. Therefore, a lifespan of the display apparatus may be reduced or power consumption may be increased.

Thus, in the display apparatus 100 according to an example embodiment of the present disclosure, a plurality of sub-pixels of one pixel PX is connected to sub-pixel circuits disposed in different pixels PX, respectively. For example, the first sub-pixel SP1 and the second sub-pixel SP2 of a pixel PX disposed in the (N)th row may be disposed more adjacent to a sub-pixel circuit disposed in the (N)th row than to a sub-pixel circuit disposed in the (N+1)th row. Also, the third sub-pixel SP3 may be disposed more adjacent to the sub-pixel circuit disposed in the (N+1)th row than to the sub-pixel circuit disposed in the (N)th row. Therefore, the first sub-pixel SP1 and the second sub-pixel SP2 are driven by a gate line GL disposed in the sub-pixel circuit disposed in the (N)th row, i.e., in the corresponding pixel. Also, the third sub-pixel SP3 is driven by a gate line GL disposed in the sub-pixel circuit disposed in the (N+1)th row, i.e., in another pixel. Therefore, an area ratio of the first anode electrode 162-3 and the second anode electrode 164-3 of the third sub-pixel SP3 on the substrate 10 may be decreased as compared to the same area. Thus, the aperture ratio of the display apparatus 100 can be improved. Therefore, in the display apparatus 100 according to an example embodiment of the present disclosure, the aperture ratio can be increased by decreasing the area where the first anode electrode 162-3 and the second anode electrode 164-3 of the third sub-pixel SP3 are disposed. Accordingly, the display apparatus 100 may be driven at a low current. Thus, the lifespan and power consumption of the display apparatus 100 may be improved.

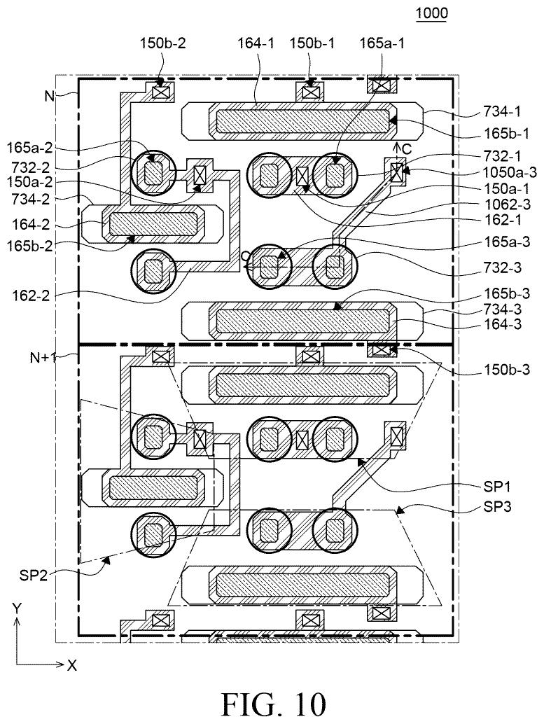

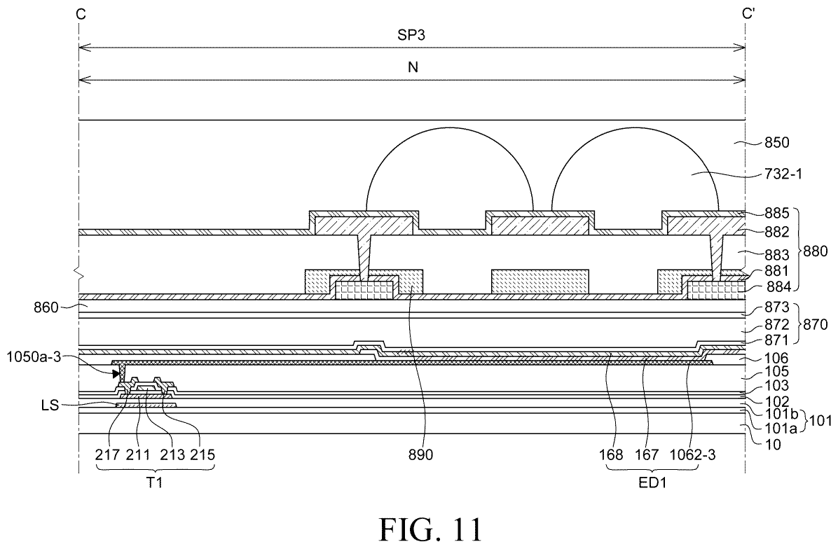

FIG. 10 is a plan view illustrating a pixel of a display apparatus according to another example embodiment of the present disclosure. FIG. 11 is an example of a cross-sectional view taken along the line C-C′ of FIG. 10. FIG. 11 is an example of a cross-sectional view of the first sub-light emitting diode ED1 of the third sub-pixel SP3. A display apparatus 1000 according to another example embodiment of the present disclosure is substantially the same as the display apparatus 100 according to an example embodiment of the present disclosure except for positions of a first anode electrode 1062-3 and a first drain contact hole 1050a-3 of the third sub-pixel SP3. Therefore, a redundant description thereof will be omitted for brevity.

The third sub-pixel SP3 includes the first anode electrode 1062-3 of the first sub-light emitting diode ED1 and the second anode electrode 164-3 of the second sub-light emitting diode ED2. The second sub-light emitting diode ED2 of the third sub-pixel SP3 may be connected to a different sub-pixel circuit than the first sub-light emitting diode ED1 of the third sub-pixel SP3.

For example, as shown in FIG. 10, the first anode electrode 1062-3 of the third sub-pixel SP3 may extend to a pixel PX disposed in the same row as the third sub-pixel SP3. Also, the second anode electrode 164-3 of the third sub-pixel SP3 may be connected to a sub-pixel circuit in a row subsequent (or adjacent) to the row of the third sub-pixel SP3. For example, with respect to the X-Y plan view, a first anode electrode 1602-3 of the third sub-pixel SP3 may extend upwards and the second anode electrode 164-3 of the third sub-pixel SP3 may extend downwards.

Therefore, as for the third sub-pixel SP3 disposed in the (N)th row, the first anode electrode 1062-3 provided in the third sub-pixel SP3 is connected to the first transistor T1 disposed in the (N)th row and corresponding to the third sub-pixel SP3 through the first drain contact hole 1050a-3. For example, as shown in FIG. 11, the first anode electrode 1062-3 of the first sub-light emitting diode ED1 in the third sub-pixel SP3 may be connected to the first transistor T1 of a pixel circuit disposed in the same row as the third sub-pixel SP3 through a contact hole penetrating the overcoating layer 105. For example, the first anode electrode 1062-3 of the first sub-light emitting diode ED1 in the third sub-pixel SP3 disposed in the (N)th row may be electrically connected to the first drain electrode 217 (or the first source electrode 215) of the first transistor T1 disposed in the (N)th row through the first drain contact hole 1050a-3.

In contrast, the second anode electrode 164-3 provided in the third sub-pixel SP3 is connected to the second transistor T2 disposed in the (N+1)th row and corresponding to the third sub-pixel SP3 through a second drain contact hole 105b-3.

Therefore, the first sub-light emitting diode ED1 of the plurality of sub-light emitting diodes ED1 and ED2 of the third sub-pixel SP3 may be driven by the same gate line GL as the plurality of sub-light emitting diodes ED1 and ED2 of the first sub-pixel SP1 and the second sub-pixel SP2. For example, the first sub-light emitting diode ED1 of the third sub-pixel SP3 as well as the plurality of sub-light emitting diodes ED1 and ED2 of the first and second sub-pixels SP1 and SP2 are driven by the same gate line GL. Also, the first sub-light emitting diode ED1 of the plurality of sub-light emitting diodes ED1 and ED2 of the third sub-pixel SP3 may be driven by a different gate line GL than the second sub-light emitting diode ED2 of the third sub-pixel SP3. For example, the first sub-light emitting diode ED1 of the third sub-pixel SP3 is driven by one gate line GL, and the second sub-light emitting diode ED2 of the third sub-pixel SP3 is driven by another gate line GL that is different from the one gate line GL. Thus, the plurality of sub-light emitting diodes ED1 and ED2 of the first sub-pixel SP1 and the second sub-pixel SP2 and the first sub-light emitting diode ED1 of the third sub-pixel SP3 may be driven by the (N)th gate line. Also, the second sub-light emitting diode ED2 of the plurality of sub-light emitting diodes ED1 and ED2 of the third sub-pixel SP3 may be driven by the (N+1)th gate line.

In the display apparatus 1000 according to another example embodiment of the present disclosure, a plurality of sub-pixels of one pixel PX is connected to sub-pixel circuits disposed in different pixels PX, respectively. For example, in a pixel PX disposed in the (N)th row, the third sub-pixel SP3, which is disposed more adjacent to (or closer to) a sub-pixel circuit disposed in the (N+1)th row than to a sub-pixel circuit disposed in the (N)th row, may be connected to the sub-pixel circuit disposed in the (N+1)th row. Thus, the aperture ratio may be increased by decreasing the area where the first anode electrode 1062-3 and/or the second anode electrode 164-3 of the third sub-pixel SP3 are disposed. Accordingly, the lifespan and power consumption of the display apparatus 1000 may be improved.

Also, in the display apparatus 1000 according to another example embodiment of the present disclosure, the plurality of sub-light emitting diodes ED1 and ED2 of a plurality of sub-pixels is connected to sub-pixel circuits disposed in different pixels PX, respectively. For example, the first sub-light emitting diode ED1 of the plurality of sub-light emitting diodes ED1 and ED2 of the third sub-pixel SP3 disposed in the (N)th row may be disposed more adjacent to (or closer to) the sub-pixel circuit disposed in the (N)th row than to the sub-pixel circuit disposed in the (N+1)th row. Also, the second sub-light emitting diode ED2 may be disposed more adjacent to (or closer to) the sub-pixel circuit disposed in the (N+1)th row than to the sub-pixel circuit disposed in the (N)th row. Thus, the first anode electrode 1062-3 of the first sub-light emitting diode ED1 of the plurality of sub-light emitting diodes ED1 and ED2 in the third sub-pixel SP3 disposed in the (N)th row may extend to the sub-pixel circuit disposed in the (N)th row. Thus, the first anode electrode 1062-3 may be connected to the sub-pixel circuit disposed in the (N)th row. Also, the second anode electrode 164-3 of the second sub-light emitting diode ED2 may extend to the sub-pixel circuit disposed in the (N+1)th row. Thus, the aperture ratio may be increased by decreasing the area where each of the first anode electrode 1062-3 and the second anode electrode 164-3 of the third sub-pixel SP3 is disposed. Accordingly, the lifespan and power consumption of the display apparatus 1000 may be improved.

In one or more aspects, a line or a horizontal pixel line may be referred to as a row, and vice versa. In one or more aspects, the terms “row” and “column” may be used interchangeably, may have a geometrical relationship in which they are perpendicular but is not limited thereto, and may have a relationship with wider directivities within the range within which the components of the present disclosure may operate functionally. In one or more aspects, an (N+1)th element may be disposed above or below an (N)th element but is not limited thereto, and these elements may have a relationship with wider directivities within the range within which the components of the present disclosure may operate functionally.

Various examples and aspects of the present disclosure are described below. These are provided as examples, and do not limit the scope of the present disclosure.

According to one or more aspects of the present disclosure, there is provided a display apparatus. The display apparatus comprises: a substrate; a plurality of pixels on the substrate in a row direction and a column direction and including a plurality of sub-pixels; a plurality of sub-pixel circuits in the plurality sub-pixels on the substrate; and a plurality of gate lines on the substrate and connected to the plurality of sub-pixel circuits, wherein each of the plurality of sub-pixels includes a plurality of sub-light emitting diodes configured to emit light of a same color, at least one sub-light emitting diode of one sub-pixel included in one of the plurality of pixels is configured to be driven by a gate line, and a sub-light emitting diode of another sub-pixel included in the same one of the plurality of pixels is configured to be driven by another gate line that is different from the gate line.

The plurality of sub-pixels may include a first sub-pixel, a second sub-pixel, and a third sub-pixel that are configured to emit light of different colors, the plurality of sub-light emitting diodes of the first sub-pixel and the second sub-pixel may be configured to be driven by a same gate line, and a first sub-light emitting diode of the plurality of sub-light emitting diodes of the third sub-pixel may be configured to be driven.

The plurality of sub-light emitting diodes of the first sub-pixel and the second sub-pixel may be configured to be driven by an (N)th gate line, and a second sub-light emitting diode of the plurality of sub-light emitting diodes of the third sub-pixel may be configured to be driven by an (N+1)th gate line.

The first sub-light emitting diode of the plurality of sub-light emitting diodes of the third sub-pixel may be configured to be driven by the same (N+1)th gate line.

The first sub-light emitting diode of the plurality of sub-light emitting diodes of the third sub-pixel may be configured to be driven by the same gate line as the first sub-pixel and the second sub-pixel.

The plurality of sub-light emitting diodes of the first sub-pixel and the second sub-pixel and the first sub-light emitting diode of the third sub-pixel may be configured to be driven by an (N)th gate line, and the second sub-light emitting diode of the plurality of sub-light emitting diodes of the third sub-pixel may be configured to be driven by an (N+1)th gate line.

In one pixel, the first sub-pixel may be disposed at an upper side of the one pixel, the third sub-pixel may be disposed at a lower side of the one pixel, and the second sub-pixel may be disposed between the first sub-pixel and the third sub-pixel.

According to one or more aspects of the present disclosure, there is provided a display apparatus. The display apparatus comprises: a substrate; a display area; a non-display area outside the display area; a plurality of pixels including a plurality of sub-pixels in the display area; a plurality of sub-pixel circuits in each of the plurality of pixels; a plurality of sub-light emitting diodes in each of the plurality of sub-pixels; a bank to cover ends of anode electrodes of the plurality of sub-light emitting diodes; and a plurality of lenses on the bank, wherein the plurality of sub-light emitting diodes in each of the plurality of sub-pixels includes a first sub-light emitting diode and a second sub-light emitting diode that are configured to emit light of a same color in a respective one of the plurality of sub-pixels, and at least one of the first sub-light emitting diode and the second sub-light emitting diode of one sub-pixel included in one pixel of the plurality of pixels is connected to a sub-pixel circuit in another pixel of the plurality of pixels.

The plurality of sub-pixels may include a first sub-pixel, a second sub-pixel, and a third sub-pixel that are configured to emit light of different colors, and an anode electrode of the first sub-light emitting diode of the third sub-pixel may extend to a pixel in a row subsequent to a row of the third sub-pixel.

The first sub-light emitting diode of the third sub-pixel may be connected to a sub-pixel circuit in the subsequent row.

The second sub-light emitting diode of the third sub-pixel may be connected to a different sub-pixel circuit than the first sub-light emitting diode of the third sub-pixel.

An anode electrode of the second sub-light emitting diode of the third sub-pixel may extend to the pixel in the row subsequent to the row of the third sub-pixel.

The second sub-light emitting diode of the third sub-pixel may be connected to a sub-pixel circuit in the subsequent row.

The first and second sub-light emitting diodes of the third sub-pixel may be connected to a same sub-pixel circuit.

The bank may include a first opening which exposes the anode electrode of the first sub-light emitting diode of the third sub-pixel, and at least one second opening which exposes an anode electrode of the second sub-light emitting diode of the third sub-pixel, the plurality of lenses may include a first lens which is disposed to cover the first opening and is configured to refract light from the first sub-light emitting diode of the third sub-pixel, and a second lens which is disposed to cover the at least one second opening and is configured to refract light from the second sub-light emitting diode of the third sub-pixel, the first opening may have a shape whose length in a row direction is equal to a length in a column direction, and the at least one second opening may have a shape whose length in the row direction is greater than a length in the column direction.

According to one or more aspects of the present disclosure, there is provided a display apparatus. The display apparatus comprises: a display area; a plurality of pixels in the display area; and a plurality of sub-pixels included in the plurality of pixels, wherein the plurality of pixels comprises a pixel and another pixel that is different from the pixel, the plurality of sub-pixels comprises a sub-pixel and another sub-pixel that is different from the sub-pixel, each of the plurality of sub-pixels comprises a plurality of sub-light emitting diodes, a sub-light emitting diode of the sub-pixel of the pixel is configured to be driven by a transistor included in the pixel, and a sub-light emitting diode of the another sub-pixel of the pixel is configured to be driven by another transistor included in the another pixel.

The display apparatus may further comprise a plurality of sub-pixel circuits in the plurality of pixels, wherein the plurality of sub-pixel circuits may comprise a sub-pixel circuit and another sub-pixel circuit, the sub-light emitting diode of the sub-pixel of the pixel may be configured to be driven by the transistor of the sub-pixel circuit of the pixel, and the sub-light emitting diode of the another sub-pixel of the pixel may be configured to be driven by the another transistor of the another sub-pixel circuit of the another pixel.

The display apparatus may further comprise a plurality of gate lines connected to a plurality of sub-pixel circuits disposed in the plurality of pixels, wherein the plurality of gate lines may comprise a gate line and another gate line different from the gate line, the sub-light emitting diode of the sub-pixel of the pixel may be configured to be driven by the gate line provided to the pixel, and the sub-light emitting diode of the another sub-pixel of the pixel may be configured to be driven by the another gate line provided to the another pixel.

Although the example embodiments of the present disclosure have been described in detail with reference to the accompanying drawings, the present disclosure is not limited thereto and may be embodied in many different forms without departing from the technical concept or the scope of the present disclosure. Therefore, the example embodiments of the present disclosure are provided for illustrative purposes only but not intended to limit the technical concept of the present disclosure. The scope of the present disclosure is not limited thereto. Therefore, it should be understood that the description herein are illustrative in all aspects and do not limit the present disclosure. The protective scope of the present disclosure should be construed based on the following claims, and all the technical concepts in the equivalent scope thereof should be construed as falling within the scope of the present disclosure. Thus, the present disclosure covers the modifications and variations of this disclosure that come within the scope of the claims and their equivalents.

What is claimed is:

1. A display apparatus, comprising:
a substrate;
a plurality of pixels on the substrate in a row direction and a column direction and including a plurality of sub-pixels;
a plurality of sub-pixel circuits in the plurality sub-pixels on the substrate; and
a plurality of gate lines on the substrate and connected to the plurality of sub-pixel circuits,
wherein each of the plurality of sub-pixels includes a plurality of sub-light emitting diodes configured to emit light of a same color as each other,
at least one sub-light emitting diode of one sub-pixel included in one of the plurality of pixels is configured to be driven by a gate line, and
a sub-light emitting diode of another sub-pixel included in the same one of the plurality of pixels is configured to be driven by another gate line that is different from the gate line.

2. The display apparatus according to claim 1, wherein the plurality of sub-pixels includes a first sub-pixel, a second sub-pixel, and a third sub-pixel that are configured to emit light of different colors,
the plurality of sub-light emitting diodes of the first sub-pixel and the second sub-pixel is configured to be driven by a same gate line, and
a first sub-light emitting diode of the plurality of sub-light emitting diodes of the third sub-pixel is configured to be driven by the same gate line or a different gate line.

3. The display apparatus according to claim 2, wherein the plurality of sub-light emitting diodes of the first sub-pixel and the second sub-pixel is configured to be driven by an (N)th gate line, and
a second sub-light emitting diode of the plurality of sub-light emitting diodes of the third sub-pixel is configured to be driven by an (N+1)th gate line.

4. The display apparatus according to claim 3, wherein the first sub-light emitting diode of the plurality of sub-light emitting diodes of the third sub-pixel is configured to be driven by the same (N+1)th gate line.

5. The display apparatus according to claim 2, wherein the first sub-light emitting diode of the plurality of sub-light emitting diodes of the third sub-pixel is configured to be driven by the same gate line as the first sub-pixel and the second sub-pixel.

6. The display apparatus according to claim 5, wherein the plurality of sub-light emitting diodes of the first sub-pixel and the second sub-pixel and the first sub-light emitting diode of the third sub-pixel are configured to be driven by an (N)th gate line, and
a second sub-light emitting diode of the plurality of sub-light emitting diodes of the third sub-pixel is configured to be driven by an (N+1)th gate line.

7. The display apparatus according to claim 2, wherein in one pixel, the first sub-pixel is disposed at an upper side of the one pixel,
the third sub-pixel is disposed at a lower side of the one pixel, and
the second sub-pixel is disposed between the first sub-pixel and the third sub-pixel.

8. A display apparatus, comprising:
a substrate;
a display area;
a non-display area outside the display area;
a plurality of pixels including a plurality of sub-pixels in the display area;
a plurality of sub-pixel circuits in each of the plurality of pixels;
a plurality of sub-light emitting diodes in each of the plurality of sub-pixels;
a bank to cover ends of anode electrodes of the plurality of sub-light emitting diodes; and
a plurality of lenses on the bank,
wherein the plurality of sub-light emitting diodes in each of the plurality of sub-pixels includes a first sub-light emitting diode and a second sub-light emitting diode that are configured to emit light of a same color in a respective one of the plurality of sub-pixels, and
at least one of the first sub-light emitting diode and the second sub-light emitting diode of one sub-pixel included in one pixel of the plurality of pixels is connected to a sub-pixel circuit in another pixel of the plurality of pixels.

9. The display apparatus according to claim 8, wherein the plurality of sub-pixels includes a first sub-pixel, a second sub-pixel, and a third sub-pixel that are configured to emit light of different colors, and
an anode electrode of the first sub-light emitting diode of the third sub-pixel extends to a pixel in a row subsequent to a row of the third sub-pixel.

10. The display apparatus according to claim 9, wherein the first sub-light emitting diode of the third sub-pixel is connected to a sub-pixel circuit in the subsequent row.

11. The display apparatus according to claim 9, wherein the second sub-light emitting diode of the third sub-pixel is connected to a sub-pixel circuit that is different from a sub-pixel circuit to which the first sub-light emitting diode of the third sub-pixel is connected.

12. The display apparatus according to claim 9, wherein an anode electrode of the second sub-light emitting diode of the third sub-pixel extends to the pixel in the row subsequent to the row of the third sub-pixel.

13. The display apparatus according to claim 12, wherein the second sub-light emitting diode of the third sub-pixel is connected to a sub-pixel circuit in the subsequent row.

14. The display apparatus according to claim 12, wherein the first and second sub-light emitting diodes of the third sub-pixel are connected to a same sub-pixel circuit.

15. The display apparatus according to claim 9, wherein the bank includes a first opening which exposes the anode electrode of the first sub-light emitting diode of the third sub-pixel, and at least one second opening which exposes an anode electrode of the second sub-light emitting diode of the third sub-pixel,
the plurality of lenses includes a first lens which is disposed to cover the first opening and is configured to refract light from the first sub-light emitting diode of the third sub-pixel, and a second lens which is disposed to cover the at least one second opening and is configured to refract light from the second sub-light emitting diode of the third sub-pixel,
the first opening has a shape whose length in a row direction is equal to a length in a column direction, and
the at least one second opening has a shape whose length in the row direction is greater than a length in the column direction.

16. A display apparatus, comprising:
a display area;
a plurality of pixels in the display area; and
a plurality of sub-pixels included in the plurality of pixels,
wherein the plurality of pixels comprises a pixel and another pixel that is different from the pixel,
the plurality of sub-pixels comprises a sub-pixel and another sub-pixel that is different from the sub-pixel,
each of the plurality of sub-pixels comprises a plurality of sub-light emitting diodes, a sub-light emitting diode of the sub-pixel of the pixel is configured to be driven by a transistor included in the pixel, and
a sub-light emitting diode of the another sub-pixel of the pixel is configured to be driven by another transistor included in the another pixel.

17. The display apparatus according to claim 16, further comprising a plurality of sub-pixel circuits in the plurality of pixels,
wherein the plurality of sub-pixel circuits comprises a sub-pixel circuit and another sub-pixel circuit,
the sub-light emitting diode of the sub-pixel of the pixel is configured to be driven by the transistor of the sub-pixel circuit of the pixel, and
the sub-light emitting diode of the another sub-pixel of the pixel is configured to be driven by the another transistor of the another sub-pixel circuit of the another pixel.

18. The display apparatus according to claim 16, further comprising a plurality of gate lines connected to a plurality of sub-pixel circuits disposed in the plurality of pixels,
wherein the plurality of gate lines comprises a gate line and another gate line different from the gate line,
the sub-light emitting diode of the sub-pixel of the pixel is configured to be driven by the gate line provided to the pixel, and
the sub-light emitting diode of the another sub-pixel of the pixel is configured to be driven by the another gate line provided to the another pixel.
